(19) United States
(12) Patent Application Publication
(10) Pub. No.: US 2024/0384115 A1
(43) Pub. Date: Nov. 21, 2024

(54) CONDUCTIVE PASTE, CONDUCTIVE FILM-COATED SUBSTRATE, AND METHOD FOR PRODUCING CONDUCTIVE FILM-COATED SUBSTRATE

(71) Applicant: TAIYO NIPPON SANSO CORPORATION, Tokyo (JP)

(72) Inventors: Kentaro MIYOSHI, Tokyo (JP); Hiroshi IGARASHI, Tokyo (JP)

(21) Appl. No.: 18/691,238

(22) PCT Filed: Sep. 26, 2022
(86) PCT No.: PCT/JP2022/035568

§ 371 Date: Mar. 12, 2024

(30) Foreign Application Priority Data
Sep. 30, 2021 (JP) 2021-160250

(51) Int. Cl. C09D 5/24; C08K 9/02; C09D 7/20; C09D 7/40; C09D 7/62; C09D 139/06; H01B 1/22; H01B 5/14

(52) U.S. Cl. CPC C09D 5/24; C09D 7/20; C09D 7/62; C09D 7/68; C09D 7/69; C09D 139/06; H01B 1/22; H01B 5/14; C08K 9/02; C08K 2201/001; C08K 2201/005; C08K 2201/006

(57) ABSTRACT

An object of the present invention is to provide a conductive paste that can form a conductive film with excellent conductivity and that does not easily scatter copper fine particles even when sintered with irradiation energy that can sufficiently remove a binder resin, a conductive film-coated film using the conductive paste, and a method for producing a conductive film-coated substrate. The present invention provides a conductive paste containing copper fine particles with an average particle size of 300 nm or less, copper coarse particles with an average particle size of 3 to 11 μm, a binder resin, and a dispersion medium, wherein a content of the binder resin is 0.1 to 2.0 parts by mass with respect to a total of 100 parts by mass of the copper fine particles and the copper coarse particles; a conductive film-coated substrate including a substrate and a sintered body of the conductive paste provided on the substrate; and a method for producing a conductive film-coated substrate including providing a film containing the conductive paste a substrate; and applying a sintering treatment to the film.

### TECHNICAL FIELD

The present invention relates to a conductive paste, a conductive film-coated substrate, and a method for producing a conductive film-coated substrate.

### BACKGROUND ART

Conductive film-coated substrates, in which conductive wiring patterns are formed on substrates such as a polyethylene terephthalate (PET) film, polyimide (PI) film, paper, and glass, are used industrially as wiring boards for RF tags, pressure-sensitive sensors, and the like. As a general method for forming a wiring pattern, a method is known in which a wiring pattern is formed by etching or the like after depositing copper on a substrate or bonding a substrate and a copper foil together.

In recent years, with the development of AI technology and IoT technology, the importance of sensor materials has increased, and cost reduction and mass production of wiring patterns are required. Forming a wiring pattern by an etching process is industrially disadvantageous in terms of cost, productivity, and environment. Therefore, expectations are increasing for printed electronics as a simpler method for forming wiring patterns. In printed electronics, for example, a pattern of a conductive paste is printed on a substrate, and then heat treatment is performed to form a conductive film on the substrate.

For example, the following (1) and (2) have been proposed as a conductive paste that can be used in printed electronics.
(1) A conductive paste including copper fine particles with an average particle diameter of 300 nm or less, copper coarse particles with an average particle size of 3 to 11 μm, a binder resin, and a dispersion medium, wherein the copper fine particles have a coating containing cuprous oxide and copper carbonate on at least a part of the surface thereof, wherein a ratio of the mass oxygen concentration with respect to the specific surface area of the copper fine particles is 0.1 to 1.2% by mass▪g/m², wherein a ratio of the mass carbon concentration with respect to the specific surface area of the copper coarse particles is 2.5 to 6 parts by mass (Patent Document 1).
(2) A conductive paste including copper fine particles with an average particle size of 10 to 100 nm, and copper coarse particles having a volume-based cumulative 50% particle diameter (D50) of 4 to 25 μm as measured by a laser diffraction particle size distribution analyzer, wherein a tap density of the copper coarse particles is 3.9 g/cm³ or less, wherein a ratio of the cumulative 90% particle diameter (D90) to the volume-based cumulative 10% particle diameter (D10) measured by a laser diffraction particle size distribution analyzer is 3.65 or more, and wherein a mass ratio of the copper fine particles with respect to the total amount of the copper fine particles and the copper coarse particles is 20% or more (Patent Document 2).

### PRIOR ART DOCUMENTS

### Patent Documents

Patent Document 1 Japanese Unexamined Patent Application, First Publication No. 2020-119737
Patent Document 2 Japanese Unexamined Patent Application, First Publication No. 2017-69012

### SUMMARY OF INVENTION

### Problem to be Solved by the Invention

A conductive film including a wiring pattern formed using a conductive paste is required to have further improved conductivity. In order to improve the conductivity, it is effective to sufficiently remove the binder resin and improve the sinterability of the copper particles by adjusting the sintering treatment conditions.

However, if the printed pattern formed with the conductive paste (1) and (2) is subjected to sintering treatment with irradiation energy that is sufficient to remove the binder resin, there is a problem in that the copper particles will scatter onto the substrate and the conductive film will likely be collapsed. As described above, unless the irradiation energy is appropriately adjusted, it is difficult to sufficiently remove the binder resin and it is difficult to improve the sinterability, so there is room for improvement in the conductivity of the conductive film. Further, according to the studies of the present inventors, the conductive film obtained from the conductive paste (2) tends to have a porous structure, and therefore has insufficient conductivity.

Therefore, an object of the present invention is to provide a conductive paste that can form a conductive film with excellent conductivity and that does not easily scatter copper fine particles even when sintered with irradiation energy that can sufficiently remove a binder resin, a conductive film-coated film using the conductive paste, and a method for producing a conductive film-coated substrate.

### Means for Solving the Problem

The present invention provides the following conductive paste, conductive film-coated substrate using the conductive paste, and method for producing a conductive film-coated substrate.
[1] A conductive paste containing copper fine particles with an average particle size of 300 nm or less, copper coarse particles with an average particle size of 3 to 11 μm, a binder resin, and a dispersion medium, wherein a content of the binder resin is 0.1 to 2.0 parts by mass with respect to a total of 100 parts by mass of the copper fine particles and the copper coarse particles.
[2] The conductive paste according to [1], wherein a mass ratio of the copper coarse particles to the copper fine particles (mass of the copper fine particles/mass of the copper coarse particles) is in a range from 30/70 to 90/10.
[3] The conductive paste according to [1] or [2], wherein a mass ratio of the copper coarse particles to the copper fine particles (mass of the copper fine particles/mass of the copper coarse particles) is in a range from 40/60 to 90/10.
[4] The conductive paste according to any one of [1] to [3], wherein the binder resin contains polyvinylpyrrolidone.
[5] The conductive paste according to any one of [1] to [4], wherein the dispersion medium contains at least one selected from the group consisting of ethylene glycol and diethylene glycol.
[6] The conductive paste according to any one of [1] to [5], wherein the copper fine particles have a coating containing cuprous oxide and copper carbonate on at least a part of the surface thereof, wherein a ratio of a mass oxygen concentration to a specific surface area of the copper fine particles is 0.1 to 1.2% by mass▪g/m², and wherein a ratio of a mass carbon concentration to a specific surface area of the copper fine particles is 0.008 to 0.3% by mass▪g/m².
[7] A conductive film-coated substrate including a substrate and a sintered body of the conductive paste according to any one of [1] to [6] provided on the substrate.
[8] A method for producing a conductive film-coated substrate, including providing a film containing a conductive paste according to any one of [1] to [6] on a substrate; and applying a sintering treatment to the film.
[9] The method for producing a conductive film-coated substrate according to [8], wherein the sintering treatment is photo-sintering.

### EFFECTS OF THE INVENTION

The present invention can provide a conductive paste capable of forming a conductive film with excellent conductivity, in which the copper fine particles are not easily scattered even when sintered with irradiation energy that can sufficiently remove the binder resin, and a conductive paste-coated film using the conductive paste, and a method for producing a conductive film-coated substrate.

### BRIEF DESCRIPTION OF DRAWINGS

FIG. 1 is a plan view of a wiring pattern used for measuring specific resistance in examples and comparative examples.

### DETAILED DESCRIPTION OF THE PREFERRED EMBODIMENTS

In the present description, “˜” indicating a numerical range means that the numerical values written before and after are included as lower and upper limits.

In the present description, the average particle diameter means the average primary particle diameter measured by the following measuring method.

### Conductive Paste

The conductive paste of the present invention contains copper fine particles with an average particle size of 300 nm or less, copper coarse particles with an average particle size of 3 to 11 μm, a binder resin, and a dispersion medium.

The conductive paste of the present invention may further contain optional components other than the copper fine particles, the copper coarse particles, the binder resin, and the dispersion medium, as long as the effects of the present invention are not impaired.

Hereinafter, the copper fine particles, the copper coarse particles, the binder resin, the dispersion medium, and the optional components will be explained in order.

### Copper Fine Particles

The average particle diameter of the copper fine particles is 300 nm or less. The average particle diameter of the copper fine particles is preferably 200 nm or less. Since the average particle diameter of the copper fine particles is 300 nm or less, the copper fine particles have excellent sinterability. Furthermore, the sintering temperature of the conductive paste can be lowered.

The average particle diameter of the copper fine particles is preferably 50 nm or more, and more preferably 100 nm or more. When the average particle diameter of the copper fine particles is within the lowest limit to the highest limit, relatively little gas is generated during sintering of the conductive paste, and cracks can be reduced when the conductive paste is formed on the conductive film. From the above, the average particle diameter of the copper fine particles is preferably 50 to 300 nm, and more preferably 100 to 200 nm.

The average particle diameter of the copper fine particles is the particle size of each copper fine particle for 250 (total, 10 fields, 2500 particles) copper fine particles present in one field of view observed using a scanning electron microscope (SEM). The diameters are measured and the arithmetic mean is taken as the average particle diameter of the copper fine particles. The criteria for selecting particles to be measured from among the particles shown in the image (photograph) of a scanning electron microscope are as follows (1) to (6).
(1) Particles that partially protrude outside the field of view of the photograph are not measured.
(2) Particles with clear outlines and isolated particles are measured.
(3) Even if the particle shape deviates from the average particle shape, particles that are independent and can be measured as individual particles are measured.
(4) If the particles overlap, but the boundary between them is clear and the shape of the entire particle can be determined, each particle is measured as a single particle.
(5) Particles that overlap and have unclear boundaries and of which the entire shape cannot be determined are not measured as the shape of the particles cannot be determined.
(6) For particles that are not perfect circles such as ellipses, the major axis is the particle diameter.

The copper fine particles preferably have a coating containing cuprous oxide and copper carbonate on at least a part of the surface thereof. When the copper fine particles contain copper carbonate in their coating, the sintering temperature of the copper fine particles can be further lowered. It is thought that the lower the content of copper carbonate in the coating, the lower the sintering temperature.

The ratio of the mass carbon concentration with respect to the specific surface area of the copper fine particles is preferably 0.008 to 0.3% by mass▪g/m², and more preferably 0.008 to 0.020% by mass▪g/m². If the ratio of the mass carbon concentration with respect to the specific surface area of the copper fine particles is 0.008 to 0.3% by mass▪g/m², the sintering temperature of the copper particles can be set even lower, and the copper fine particles can be sintered at a lower temperature.

The ratio of the mass carbon concentration with respect to the specific surface area of the copper fine particles can be calculated from the measured specific surface area and the measured mass carbon concentration. The specific surface area can be measured using a nitrogen gas BET adsorption device (for example, “MACSORB HM-1201” manufactured by Mountech Co., Ltd.). The mass carbon concentration can be measured using a carbon-sulfur analyzer (for example, “EMIA-920V” manufactured by Horiba, Ltd.).

When the copper fine particles have a coating containing cuprous oxide and copper carbonate on at least a part of the surface thereof, the ratio of the mass oxygen concentration with respect to the specific surface area of the copper fine particles is preferably 0.1 to 1.2% by mass▪g/m², and 0.2 to 0.5% by mass▪g/m² is more preferable.

When the ratio of the mass oxygen concentration with respect to the specific surface area of the copper fine particles is 0.1% by mass▪g/m² or more, the chemical stability of the copper fine particles is improved, and phenomena such as combustion and heat generation of the copper fine particles are hardly occurred. When the ratio of the mass oxygen concentration with respect to the specific surface area of the copper fine particles is 1.2% by mass▪g/m² or less, there are fewer copper oxides, and the copper fine particles are easily sintered. As a result, the sintering temperature of the conductive paste decreases. The surface of the copper fine particles is oxidized by the air, and an oxide film is inevitably formed, so the lower limit of the ratio of the mass oxygen concentration with respect to the specific surface area of the copper fine particles is 0.1% by mass▪g/m².

The ratio of the mass oxygen concentration with respect to the specific surface area of the copper fine particles can be measured using an oxygen nitrogen analyzer (for example, “TC600” manufactured by LECO).

The copper fine particles can be produced by a production method described in Japanese Unexamined Patent Application, First Publication No. 2018-127657.

For example, by adjusting the amount of carbon in the fuel gas supplied to the burner, the ratio of the mass carbon concentration with respect to the specific surface area of the copper fine particles can be controlled to 0.008 to 0.3% by mass▪g/m².

### Copper Coarse Particles

The copper coarse particles are copper particles with an average particle diameter of 3 to 11 μm. The average particle diameter of the copper coarse particles is preferably 3 to 7 μm.

Since the average particle diameter of the copper coarse particles is 3 μm or more, the shrinkage of the copper fine particles during sintering is reduced, and cracks can be reduced when a conductive film is formed. Further, since the average particle diameter of the copper coarse particles is 11 μm or less, the conductive paste can be sufficiently sintered while maintaining the shrinkage reduction effect of the copper fine particles. As a result, a conductive film with excellent conductivity can be formed.

The average particle diameter of the copper coarse particles is the particle size of each copper coarse particle for 250 (total, 10 fields, 2500 particles) copper coarse particles present in one field of view observed using a scanning electron microscope (SEM). The diameters are measured and the arithmetic mean is taken as the average particle diameter of the copper coarse particles. The criteria for selecting particles to be measured from among the particles shown in the image (photograph) of a scanning electron microscope are as follows (1) to (6).
(1) Particles that partially protrude outside the field of view of the photograph are not measured.
(2) Particles with clear outlines and isolated particles are measured.
(3) Even if the particle shape deviates from the average particle shape, particles that are independent and can be measured as individual particles are measured.
(4) If the particles overlap, but the boundary between them is clear and the shape of the entire particle can be determined, each particle is measured as a single particle.
(5) Particles that overlap and have unclear boundaries and of which the entire shape cannot be determined are not measured as the shape of the particles cannot be determined.
(6) For particles that are not perfect circles such as ellipses, the major axis is the particle diameter.

The copper coarse particles preferably have a flat flake shape. When using copper coarse particles that are flat flakes, the density of a film obtained by coating the conductive paste on the substrate and drying becomes lower, making it easier for the gas generated during sintering to escape. Therefore, when the copper coarse particles in a flat flake shape are used in a conductive film, cracks are less likely to occur.

The tap density of the copper coarse particles is preferably 2 to 6 g/cm³, and more preferably 4 to 6 g/cm³.

When the tap density of the copper coarse particles is 2 g/cm³ or more, the conductive paste can be further sufficiently sintered while maintaining the shrinkage reduction effect of the copper fine particles, and the conductivity of the conductive film is further improved. If the tap density of the copper coarse particles is 6 g/cm³ or less, the density of the film after coating the conductive paste on the substrate and drying becomes low, making it easier for gas generated during sintering to escape. Therefore, when it is made into a conductive film, cracks are less likely to occur.

The tap density (g/cm³) of the copper coarse particles can be measured using a tap density meter (for example, “KYT-4000” manufactured by Seishin Enterprise Co., Ltd.).

### Dispersion Medium

The dispersion medium is not particularly limited as long as it is a compound that can disperse the copper fine particles and the copper coarse particles. Examples of the dispersion medium include water; alcohols such as methanol, ethanol, 1-propanol, 2-propanol (IPA), and terpineol; polyols such as ethylene glycol, diethylene glycol, and triethylene glycol; and polar media such as N,N-dimethylformamide (DMF), and N-methylpyrrolidone (NMP). These dispersion media may be used alone or in combination of two or more.

Among these dispersion media, because of the reducing effect of the copper fine particles, the dispersion medium preferably contains at least one selected from the group consisting of ethylene glycol and diethylene glycol.

### Binder Resin

The binder resin is not particularly limited as long as it is a compound that can impart appropriate viscosity to the conductive paste and impart adhesion to the substrate when formed into a conductive film.

Examples of the binder resin include cellulose derivatives such as carboxylcellulose, ethylcellulose, cellulose ether, carboxylethylcellulose, aminoethylcellulose, oxyethylcellulose, hydroxymethylcellulose, hydroxyethylcellulose, hydroxylpropylcellulose, methylcellulose, benzylcellulose, and trimethylcellulose: acrylic polymer such as methyl (meth)acrylate, ethyl(meth)acrylate, butyl(meth)acrylate, benzyl(meth)acrylate, hydroxyethyl(meth)acrylate, dimethylaminoethyl acrylate, acrylic acid, and methacrylic acid; and nonionic surfactants such as polyvinyl alcohol and polyvinylpyrrolidone. However, the binder resin is not limited to these examples.

Among these, polyvinylpyrrolidone is preferable as the binder resin since it improves the dispersibility of the copper fine particles. In addition to functioning as a binder resin, polyvinylpyrrolidone can also function as a dispersant for the copper fine particles and the copper coarse particles. When polyvinylpyrrolidone is used as the binder resin, the dispersibility of the copper fine particles is improved and there is no need to use a dispersant together. As a result, the number of components in the conductive paste can be reduced. Therefore, the number of components that can affect the two properties of the copper fine particles, namely the sinterability and adhesion to the substrate when formed into a conductive film, can be reduced.

### Optional Component

An example of the optional component is a dispersant. Examples of the dispersant include hexametaphosphate sodium salt, and β-naphthalenesulfonic acid formalin condensate sodium salt. These dispersants may be used alone or in combination of two or more.

The dispersant is preferably a compound that can be decomposed and removed during sintering.

### Content

The content of the copper fine particles is preferably 10 to 60% by mass, and more preferably 20 to 30% by mass with respect to the total of 100% by mass of the copper fine particles and the copper coarse particles.

When the content of the copper fine particles is 10% by mass or more with respect to the total of 100% by mass of the copper fine particles and the copper coarse particles, the conductive paste can be sufficiently sintered, and the conductivity of the conductive film is further improved.

When the content of the copper fine particles is 60% by mass or less with respect to the total of 100% by mass of the copper fine particles and the copper coarse particles, the shrinkage of the copper fine particles during sintering is further reduced, and when formed into a conductive film, cracks are less likely to occur.

The mass ratio of the copper coarse particles to the copper fine particles (mass of the copper fine particles/mass of the copper coarse particles) is preferably from 30/70 to 90/10, and more preferably from 40/60 to 90/10.

When the mass ratio of the copper coarse particles to the copper fine particles is 30/70 or more, scattering of the copper particles is reduced when forming a conductive film, and the conductive film is less likely to collapse even if the sintering treatment conditions are made stricter.

When the mass ratio of the copper coarse particles to the copper fine particles is 90/10 or less, the conductive paste can be sufficiently sintered while maintaining the shrinkage reduction effect of the copper fine particles, and the conductivity of the conductive film is further improved.

The content of the binder resin is 0.1 to 2.0 parts by mass, and more preferably 0.1 to 0.5 parts by mass, with respect to a total of 100 parts by mass of the copper fine particles and the copper coarse particles.

Since the binder resin content is 0.1 parts by mass or more with respect to 100 parts by mass of the copper fine particles and the copper coarse particles, good dispersibility and substrate adhesion of the copper fine particles can be obtained, and when a conductive film is formed, conductivity is improved.

Since the content of the binder resin is 2.0 parts by mass or less with respect to 100 parts by mass of the copper fine particles and the copper coarse particles, the amount of decomposed gas from the binder resin generated during sintering is reduced, making it difficult for the conductive film to form cracks and scattering of the copper particles during photo-sintering, resulting in improved conductivity when made into a conductive film.

The content of the dispersion medium is preferably 15 to 30 parts by mass, and more preferably 17 to 25 parts by mass, with respect to 100 parts by mass of the copper fine particles and the copper coarse particles. When the content of the dispersion medium is equal to or higher than the above lower limit, the dispersibility of the copper fine particles and the copper coarse particles is excellent. When the content of the dispersion medium is equal to or less than the upper limit, a conductive film with excellent conductivity can be easily formed.

### Effect

In the conductive paste of the present invention described above, the content of the binder resin is 2.0 parts by mass or less with respect to 100 parts by mass of the copper fine particles and the copper coarse particles. Therefore, even when sintering with irradiation energy that is sufficient to remove the binder resin, the amount of gas generated by thermal decomposition of the binder resin and the solvent residue during sintering is reduced. Therefore, the copper particles are less likely to scatter and the conductive film is less likely to collapse on the substrate. More specifically, even if the irradiation energy is increased so that the resistance is the lowest, the copper particles are less likely to scatter and the conductive film is less likely to collapse on the substrate. Therefore, the sinterability of the copper fine particles is improved, and a conductive film with excellent conductivity can be formed. Further, since the content of the binder resin is 0.1 parts by mass or more with respect to the total of 100 parts by mass of the copper fine particles and the copper coarse particles, the adhesion of the conductive film to the substrate is also sufficiently maintained.

According to the conductive paste of the present invention explained above, even if the irradiation energy is high enough to sufficiently remove the binder resin, or specifically, even if the irradiation energy is increased so that the resistance is the lowest, the copper particles are less likely to scatter. In addition, the conductive paste of the present invention has excellent sinterability of the copper fine particles themselves and sinterability between the copper fine particles and the copper coarse particles, and can achieve a specific resistance of 10 μΩ▪·cm or less without performing a post-process such as pressing.

Furthermore, according to the conductive paste of the present invention, since the sintering temperature of the copper fine particles is low, a conductive film can be formed on the substrate at a lower temperature than conventional products. Therefore, the thermal load on the substrate during sintering is less than that of conventional products, improving the durability of the conductive film-coated substrate.

### Production Method

The conductive paste of the present invention can be produced by a method including, for example, the following step 1 and step 2.
Step 1: A step of pre-kneading the copper fine particles, the copper coarse particles, the binder resin, the dispersion medium, and, if necessary, the dispersant.
Step 2: A step of dispersing the pre-kneaded paste obtained in Step 1 using a dispersing machine such as a three-roll mill or a bead mill.

In the preliminary kneading in Step 1, a kneading machine such as a rotation and revolution type mixer, a mixer, a mortar, and the like can be used. The mixture may be kneaded while being deaerated.

In the dispersion process of step 2, if it is difficult to disperse the copper fine particles into the dispersion medium in one dispersion process, the dispersion process may be performed multiple times.

### Conductive Film-Coated Substrate

The conductive film-coated substrate of the present invention includes a substrate and a sintered conductive paste of the present invention provided on the substrate. Below, the substrate and the sintered conductive paste will be explained in order.

The substrate is not particularly limited as long as it can withstand sintering treatment. Examples of the substrate include a glass substrate; a resin substrate containing resins such as polyamide, polyimide, polyethylene, epoxy resin, phenol resin, polyester resin, polyethylene terephthalate (PET), and polyethylene naphthalate (PEN); and a paper substrate.

Among these, a polyimide substrate, a glass substrate, and a paper substrate which can withstand high irradiation energy to sufficiently remove the binder resin are preferable.

The sintering treatment of the conductive paste is considered to include a fused product in which the copper fine particles are sintered together, a fused product in which the copper coarse particles themselves are sintered, and a fused product in which the copper fine particles and the copper coarse particles are sintered. These multiple types of fused materials may be difficult to distinguish from each other after sintering because the shapes of the copper fine particles and the copper coarse particles change during sintering.

The binder resin and the dispersion medium are vaporized and decomposed and removed during the sintering treatment. Therefore, the binder resin and the dispersion medium are usually not included in the sintered conductive paste. However, as long as the effects of the invention are not impaired, residues generated from the binder resin and the dispersion medium may be included in the sintered conductive paste.

The conductive film as a sintered material provided on the substrate has electrical conductivity.

The specific resistance of the conductive film is, for example, preferably less than 15 μΩ▪·cm, more preferably less than 10 μΩ▪·cm, and even more preferably less than 8.0 μΩ▪·cm. When the specific resistance is less than 15 μΩ▪·cm, it can be said that the conductive film has excellent conductivity. The specific resistance can be measured with a digital tester M-02N manufactured by CUSTOM.

The thickness of the conductive film is, for example, preferably 5 to 30 μm, and more preferably 10 to 25 μm. When the thickness of the conductive film is 5 μm or more, the resistance of the conductive film is reduced. When the thickness of the conductive film is 30 μm or less, the adhesion of the conductive film to the substrate is excellent. The film thickness is determined by the method described in EXAMPLES.

Since the conductive film-coated substrate of the present invention described above includes the sintered conductive paste of the present invention, the conductive film has excellent conductivity.

The conductive film-coated substrate of the present invention can be used in, for example, printed wiring boards, wireless substrates such as RF tags, pressure-sensitive sensor sheets, transparent conductive films, and the like.

### Production Method for Conductive Film-Coated Substrate

The conductive film-coated substrate of the present invention can be produced by providing a film containing the conductive paste on the substrate, and then subjecting the film to sintering treatment.

For example, the conductive film-coated substrate of the present invention can be produced by coating the conductive paste on the substrate to provide a film containing the conductive paste on the substrate, and then subjecting the film containing the conductive paste to sintering treatment.

The method for coating the conductive paste on the substrate is not particularly limited. For example, various printing methods such as screen printing, inkjet printing, and gravure printing can be employed. The method for coating the conductive paste is not limited to these examples.

By carrying out the sintering treatment, the copper fine particles are sintered with each other, and the conductive film having electrical conductivity is provided on the substrate.

With a conventional conductive paste, when sintering is carried out with irradiation energy that is sufficient to remove the binder resin, for example, if the irradiation energy is increased during sintering treatment, decomposed gas from the binder and the dispersant is released. This causes scattering of the copper particles, many cracks, and voids, which makes it difficult to increase the irradiation energy so as to minimize the resistance, and also makes it difficult to increase the conductivity. As a result, organic matter remains and sinterability is insufficient, resulting in insufficient conductivity. According to studies by the present inventors, the photo-irradiation energy in the conductive paste of Patent Document 1 can only be increased to about 5 J/cm².

On the other hand, in the present invention, even if irradiation energy of 7.65 J/cm² or more is used, which facilitates sintering, the amount of decomposed gas generated can be suppressed. Therefore, a sintered film with high sinterability can be obtained, and a conductive film with excellent conductivity can be formed.

The sintering treatment is not particularly limited as long as it can sinter the copper fine particles in the conductive paste. Examples of sintering treatments include heat-sintering and photo-sintering. Among these, photo-sintering is carried out because it is easy to remove the binder resin sufficiently and form a conductive film with even better conductivity. Specific examples of the sintering treatment include a method in which a substrate provided with a film containing a conductive paste is sintered at high temperature; a method in which a film containing a conductive paste is irradiated with a light beam such as a laser and sintered by photo-irradiation; and photolithography. Specific aspects of the sintering treatment are not limited to these examples.

### Photo-Sintering

The conditions of the photo-sintering can be adjusted according to the composition of the conductive paste by using a device equipped with a xenon lamp, for example, and adjusting the lamp output and irradiation time.

By increasing the output energy or increasing the irradiation time, the temperature of the sample can be raised, making it easier to sinter the copper fine particles themselves or the copper fine particles and the copper coarse particles.

The output during photo-sintering is, for example, preferably 350V to 450V, and more preferably 400V to 440V. When the output is equal to or higher than the lower limit, the binder resin can be sufficiently removed and the sinterability of the copper particles can be improved. As a result, a conductive film with even better conductivity can be formed. When the output is equal to or lower than the upper limit, the copper particles are less likely to scatter and the conductive film is less likely to collapse. It is also advantageous in terms of cost.

The irradiation time of the photo-sintering is, for example, preferably 3000 μS to 60000 μS, and more preferably 3500 μS to 10000 μS. When the irradiation time is equal to or higher than the lower limit, the binder resin can be sufficiently removed and the sinterability of the copper particles can be easily improved. As a result, a conductive film with even better conductivity can be formed. When the irradiation time is equal to or lower than the upper limit, the copper particles are less likely to scatter and the conductive film is less likely to collapse. Moreover, industrial mass productivity is also improved.

The irradiation energy of the photo-sintering is, for example, preferably 7.65 to 16 J/cm², and more preferably 8.5 to 13 J/cm². When the irradiation energy is equal to or higher than the lower limit, the binder resin can be sufficiently removed and the sinterability of the copper particles can be easily improved. As a result, a conductive film with even better conductivity can be formed. When the irradiation energy is equal to or less than the upper limit, the copper particles are less likely to scatter and the conductive film is less likely to collapse. It is also advantageous in terms of cost.

### Heat-Sintering

The heat-sintering conditions can also be adjusted depending on the composition of the conductive paste.

By increasing the treatment temperature or lengthening the treatment time, the copper fine particles themselves or the copper fine particles and copper coarse particles can be easily sintered.

The treatment temperature during heat-sintering can be set according to the heat resistance of the substrate. For example, the temperature is preferably 200 to 400° C., and more preferably 250 to 300° C. When the treatment temperature is equal to or higher than the lower limit, the binder resin can be sufficiently removed and the sinterability of the copper particles can be easily improved. As a result, a conductive film with even better conductivity can be formed. When the treatment temperature is equal to or lower than the upper limit, cracks are less likely to occur in the conductive film and substrate deformation is also reduced. It is also advantageous in terms of cost.

The heat-sintering treatment time is preferably, for example, 5 minutes to 120 minutes, and more preferably 15 minutes to 60 minutes. When the treatment time is equal to or longer than the lower limit, the binder resin can be sufficiently removed and the sinterability of the copper particles can be easily improved. As a result, a conductive film with even better conductivity can be formed. When the heat-sintering time is equal to or shorter than the upper limit, cracks are less likely to occur in the conductive film and deformation of the substrate is also reduced. Moreover, industrial mass productivity is also improved.

### EXAMPLES

Hereinafter, the present invention will be specifically explained with reference to Examples, but the present invention is not limited to the following description.

### Copper Fine Particles

Copper fine particles were produced by the production method described in Japanese Unexamined Patent Application, First Publication No. 2018-127657. The copper fine particles produced were used in all examples and comparative examples. The average particle diameter of the copper fine particles was 110 nm, the specific surface area was 5.602 m²/g, the mass oxygen concentration was 1.1204% by mass, and the mass carbon concentration was 0.119883% by mass. The mass oxygen concentration with respect to the specific surface area calculated from these measurement results was 0.200% by mass▪g/m², and the mass carbon concentration with respect to the specific surface area was 0.0214% by mass▪g/m².

### Copper Coarse Particles

MA-C03KP: trade name, manufactured by MITSUI MINING & SMELTING CO.,LTD (average particle size: 3.8 μm, tap density: 5.26 g/cm³).
FCC-TB: trade name, manufactured by Fukuda Metal Foil & Powder Industries Co., Ltd. (average particle size: 6.22 μm, tap density: 2.57 g/cm³).
MA-C03K: trade name, manufactured by MITSUI MINING & SMELTING CO.,LTD (average particle size: 3.21 μm, tap density: 5.00 g/cm³).

### Binder Resin

In all examples and comparative examples, polyvinylpyrrolidone (PVP, “K-85N” manufactured by Nippon Shokubai Co., Ltd.) was used as the binder resin.

### Dispersion Medium

Ethylene glycol (EG) was used as the dispersion medium in all examples and comparative examples.

### Example 1

The copper fine particles: 2.4 g, and the copper coarse particles: 5.6 g, PVP: 0.16 g, and EG: 1.86 g were pre-kneaded using a kneader (“AR-100” manufactured by Shinky Co., Ltd.), and a pre-kneaded paste was obtained. The obtained pre-kneaded paste was subjected to a dispersion treatment using a three-roll dispersion machine (“BR-100V” manufactured by Imex Corporation) to prepare a conductive paste.

Next, the conductive paste was coated onto a polyimide (PI) film (thickness: 50 μm, Kapton film “200EN” manufactured by DuPont-Toray Co., Ltd.) by screen printing to form a wiring pattern. The wiring width of the wiring pattern was 1 mm, and the wiring length was 124 mm because a 124 mm RF tag pattern wiring cut in half was used. Thereafter, the conductive paste was sintered using a photo-sintering device (Novacentrix “PulseForge Invent”) to photo-sinter the conductive paste, producing a PI film provided with a conductive film that formed a wiring pattern with a wiring width of 1 mm and a wiring length of 124 mm. Photo-sintering was carried out under relatively strong irradiation conditions that easily sintered the copper fine particles themselves and the copper fine particles and the copper coarse particles, output: 350 to 450 V, irradiation time: 3000 μS or more, irradiation energy: 7.65 J/cm² or more. Thereby, a conductive film was formed on the PI film.

For photo-sintering, changing the type of substrate or paste composition will change how the pyrolysis gas generated during photo-sintering is released and the instantaneous amount of pyrolysis gas generated, so the optimal photo-sintering conditions must be determined for each substrate and paste composition. In the present example, the optical sinter conditions were optimized as follows.
(1) The irradiation time was fixed at 4000 μS to optimize the irradiation output.
(2) Irradiation time was optimized under the optimal output obtained in (1).

Once the output and irradiation time were determined, the photo-sintering conditions were automatically calculated using simulation software inside the device. Among the sintered products in the above study, the sintering conditions that resulted in the lowest resistance were determined as the optimal optical sintering conditions.

### Examples 2 to 14, 16, and 17, and Comparative Examples 1 to 3

A conductive paste of each example was prepared in the same manner as in Example 1, except that the composition of the conductive paste was changed as shown in Table 1 or Table 2, and a conductive film was formed on the PI film.

### Example 15

A conductive film was formed on the substrate by heat-sintering using a conductive paste having the composition of Example 10.

Using a Unitemp reflow oven, after pre-oxidizing in air at 250° C. for 30 minutes, 3% H₂ gas was flowed for 30 minutes while the temperature was kept at 250° C., then switched to N₂ gas, cooled to room temperature, and the sample was taken out. Thereby, a conductive film was formed on the PI film by sintering.

### Measurement Method

### Specific Resistance

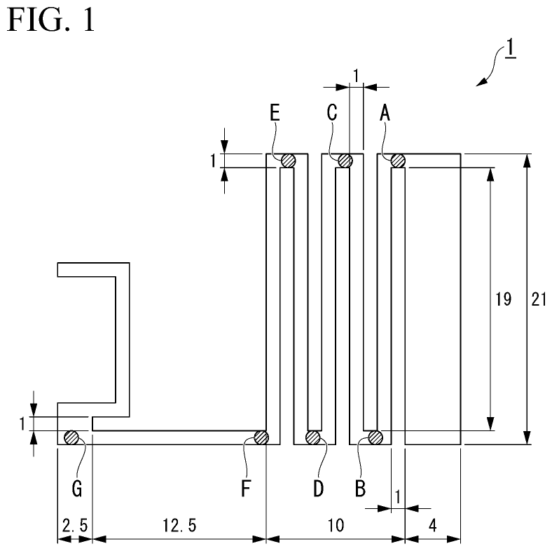

The conductivity of the conductive film in each example and conductive example was evaluated by measuring the specific resistance using a wiring pattern 1 shown in FIG. 1. Between the line length of 124 mm of the wiring pattern 1, a point A was fixed, and a specific resistance between AB: 22 mm, AC: 44 mm, AD: 66 mm, AE: 88 mm, AF: 110 mm, and AG: 124 mm were measured. A digital tester M-02N manufactured by CUSTOM was used to measure the specific resistance. Thereafter, the line length was plotted on the horizontal axis and the specific resistance was plotted on the vertical axis, and the slope of the linear function that fitted each plot was determined, and the slope was taken as the surface resistance.

### Thickness of Conductive Film

The thickness of the conductive film of each example and comparative example was measured at five locations using a laser microscope (“VK-X” manufactured by Keyence Corporation), and the average value was determined. The specific resistance was calculated by multiplying the surface resistance by the average film thickness.

TABLE 1

| | Example | Example | Example | Example | Example | Example | Example | Example | Example | Example |
|---|---|---|---|---|---|---|---|---|---|---|
| | 1 | 2 | 3 | 4 | 5 | 6 | 7 | 8 | 9 | 10 |
| Cu concentration [%] | 80 | 80 | 85 | 85 | 85 | 80 | 80 | 85 | 80 | 85 |
| Content of binder | 2 | 0.5 | 0.5 | 0.25 | 0.1 | 0.5 | 0.5 | 0.25 | 0.5 | 0.25 |
| resin to total 100 | | | | | | | | | | |
| mass parts of copper | | | | | | | | | | |
| fine particles and | | | | | | | | | | |
| copper coarse particles | | | | | | | | | | |
| [part by mass] | | | | | | | | | | |
| Mass of copper | 70/30 | 70/30 | 70/30 | 70/30 | 70/30 | 40/60 | 50/50 | 60/40 | 80/20 | 80/20 |
| fine particles/ | | | | | | | | | | |
| Mass of copper coarse | | | | | | | | | | |
| particles [—] | | | | | | | | | | |
| Copper coarse particles | MA- | MA- | MA- | MA- | MA- | MA- | MA- | MA- | MA- | MA- |
| | CO3KP | CO3KP | CO3KP | CO3KP | CO3KP | CO3KP | CO3KP | CO3KP | CO3KP | CO3KP |
| Substrate | PI | PI | PI | PI | PI | PI | PI | PI | PI | PI |
| Dispersion medium | EG | EG | EG | EG | EG | EG | EG | EG | EG | EG |
| Resistance | 0.9 | 0.6 | 0.4 | 0.2 | 0.5 | 0.6 | 0.6 | 0.6 | 0.6 | 0.4 |
| between 124 mm | | | | | | | | | | |
| Output [V] | 415 | 400 | 400 | 440 | 400 | 390 | 390 | 380 | 400 | 440 |
| Irradiation time [μS] | 50000 | 9000 | 7500 | 4000 | 4000 | 9000 | 50000 | 4000 | 9000 | 4000 |
| Irradiation energy | 15 | 11.7 | 11.1 | 11 | 8.69 | 11 | 13.3 | 7.65 | 11.7 | 11 |
| [J/cm²] | | | | | | | | | | |
| Surface resistance [Ω/□] | 0.0085 | 0.0065 | 0.0044 | 0.0023 | 0.0053 | 0.0063 | 0.0061 | 0.006 | 0.0061 | 0.0045 |
| Thickness of | 11.7 | 14.1 | 15.8 | 16.4 | 15.3 | 15.2 | 14.8 | 16.4 | 13.3 | 16.9 |
| conductive film [μm] | | | | | | | | | | |
| Specific | 9.9 | 9.2 | 7.0 | 3.8 | 8.1 | 9.6 | 9.0 | 9.8 | 8.1 | 7.6 |
| resistance [μΩ · cm] | | | | | | | | | | |

TABLE 2

| | | | | | | | | Comp. | Comp. | Comp. |
|---|---|---|---|---|---|---|---|---|---|---|
| | Example | Example | Example | Example | Example | Example | Example | Example | Example | Example |
| | 11 | 12 | 13 | 14 | 15 | 16 | 17 | 1 | 2 | 3 |
| Cu concentration [%] | 85 | 80 | 85 | 85 | 85 | 80 | 80 | 80 | 85 | 85 |
| Content of binder resin | 0.25 | 2 | 0.5 | 0.1 | 0.25 | 0.25 | 0.5 | 2.5 | 0 | 0.25 |
| to total 100 mass | | | | | | | | | | |
| parts of copper fine | | | | | | | | | | |
| particles and copper | | | | | | | | | | |
| coarse particles | | | | | | | | | | |
| [part by mass] | | | | | | | | | | |
| Mass of copper | 90/10 | 70/30 | 50/50 | 70/30 | 80/20 | 30/70 | 30/70 | 70/30 | 70/30 | 100/0 |
| fine particles/ | | | | | | | | | | |
| Mass of copper coarse | | | | | | | | | | |
| particles [—] | | | | | | | | | | |
| Copper coarse | MA- | FCC-TB | MA- | MA- | MA- | MA- | MA- | MA- | MA- | MA- |
| particles | CO3KP | | CO3KP | CO3KP | CO3KP | CO3KP | CO3KP | CO3KP | CO3KP | CO3KP |
| Substrate | PI | PI | PI | PI | PI | PI | PI | PI | PI | PI |
| Dispersion medium | EG | EG | EG | EG | EG | EG | EG | EG | EG | EG |
| Resistance | 0.6 | 0.9 | 0.6 | 0.5 | — | 0.9 | 0.7 | OVER | OVER | 1.9 |
| between 124 mm | | | | | | | | | | |
| Output [V] | 440 | 425 | 350 | 430 | — | 390 | 390 | 400 | 400 | 440 |
| Irradiation time [μS] | 4000 | 30000 | 60000 | 3500 | — | 7000 | 7000 | 4000 | 4000 | 4000 |
| Irradiation energy | 11 | 15.5 | 10.8 | 9.72 | — | 10.2 | 10.2 | 11 | 8.69 | 11 |
| [J/cm²] | | | | | | | | | | |
| Surface resistance [Ω/□] | 0.0063 | 0.0085 | 0.0063 | 0.0052 | 0.0048 | 0.0093 | 0.0071 | — | — | 0.0194 |
| Thickness of conductive | 15.7 | 10.4 | 12.9 | 15.8 | 15.2 | 15.8 | 15.2 | — | — | 15.4 |
| film [μm] | | | | | | | | | | |
| Specific resistance | 9.9 | 8.8 | 8.1 | 8.2 | 7.3 | 14.7 | 10.8 | — | — | 29.9 |
| [μΩ · cm] | | | | | | | | | | |

In Tables 1 and 2, “Cu concentration (%)” indicates “the ratio of the total amount of the copper fine particles and the copper coarse particles with respect to 100 parts by mass of the conductive paste”, and was calculated using the following formula.

$$( Cu concentration ) ( \% ) = ( mass of the copper fine particles + mass of the copper coarse particles ) \times 100 / ( mass of the copper fine particles + mass of the copper coarse particles + mass of the solvent + mass of the binder resin + mass of the dispersion medium )$$

### Results

In Examples 1 to 14, the copper fine particles did not scatter on the substrate and the conductive film did not collapse even when sintering was performed with irradiation energy that could sufficiently remove the binder resin. Furthermore, a conductive film with excellent conductivity could be formed.

Even in the case of heat-sintering as in Example 15, no substrate deformation or conductive film cracking was observed. Furthermore, a conductive film with excellent conductivity could be formed.

Even in Examples 16 and 17, the copper fine particles were not scattered on the substrate, and the conductive film did not collapse. Since the ratio of the copper fine particles was high compared to other examples, the sintering properties were good, but some cracks occurred in the sintered conductive film. Even so, the specific resistance was 15 μΩ·▪cm, and the conductivity was sufficient. Even if a circuit had cracks, the effects of the cracks could be reduced by performing additional work (touching) to improve the adhesion of the membrane.

In Comparative Example 1, since the content of the binder resin was too high, many craters and cracks were observed in the sintered conductive film, which appeared to be caused by the escape of decomposed gas, the copper particles were scattered, and the conductive film also collapsed. Moreover, the resistance was OVERLOAD.

In Comparative Example 2, since no binder resin was used, there was no adhesion between the substrate and the conductive film, and the sintered conductive film peeled off from the substrate, making it impossible to obtain a conductive film on the substrate.

In Comparative Example 3, since the copper fine particles were not used, it was difficult to sinter the copper coarse particles, resulting in a specific resistance of 15 μΩ·▪cm or more and insufficient conductivity.

### INDUSTRIAL APPLICABILITY

According to the present invention, a conductive paste capable of forming a conductive film with excellent conductivity can be provided, in which the copper fine particles are not easily scattered even when sintered with irradiation energy that can sufficiently remove the binder resin, a conductive film-coated substrate using the conductive paste, and a method for producing a conductive film-coated substrate.

### EXPLANATION OF REFERENCE NUMERALS

1 wiring pattern
A to G point in wiring pattern

1. A conductive paste containing copper fine particles with an average particle size of 300 nm or less, copper coarse particles with an average particle size of 3 to 11 μm, a binder resin, and a dispersion medium, wherein a content of the binder resin is 0.1 to 2.0 parts by mass with respect to a total of 100 parts by mass of the copper fine particles and the copper coarse particles.

2. The conductive paste according to claim 1, wherein a mass ratio of the copper coarse particles to the copper fine particles (mass of the copper course particles/mass of the copper fine particles) is in a range from 30/70 to 90/10.

3. The conductive paste according to claim 1, wherein a mass ratio of the copper coarse particles to the copper fine particles (mass of the copper course particles/mass of the copper fine particles) is in a range from 40/60 to 90/10.

4. The conductive paste according to claim 1, wherein the binder resin contains polyvinylpyrrolidone.

5. The conductive paste according to claim 1, wherein the dispersion medium contains at least one selected from the group consisting of ethylene glycol and diethylene glycol.

6. The conductive paste according to claim 1, wherein the copper fine particles have a coating containing cuprous oxide and copper carbonate on at least a part of the surface thereof, wherein a ratio of a mass oxygen concentration to a specific surface area of the copper fine particles is 0.1 to 1.2% by mass▪g/m², and wherein a ratio of a mass carbon concentration to a specific surface area of the copper fine particles is 0.008 to 0.3% by mass▪g/m².

7. A conductive film-coated substrate including a substrate and a sintered body of the conductive paste according to claim 1 provided on the substrate.

8. A method for producing a conductive film-coated substrate, including providing a film containing a conductive paste according to claim 1 on a substrate; and applying a sintering treatment to the film.

9. The method for producing a conductive film-coated substrate according to claim 8, wherein the sintering treatment is photo-sintering.
